(19) United States
(12) Patent Application Publication
(10) Pub. No.: US 2020/0183922 A1
(43) Pub. Date: Jun. 11, 2020

(54) NEAREST NEIGHBOR SEARCH LOGIC CIRCUIT WITH REDUCED LATENCY AND POWER CONSUMPTION

(71) Applicant: Intel Corporation, Santa Clara, CA (US)

(72) Inventors: Wootaek LIM, Ann Arbor, MI (US); Minchang CHO, Ann Arbor, MI (US); Somnath PAUL, Hillsboro, OR (US); Charles AUGUSTINE, Portland, OR (US); Suyoung BANG, Hillsboro, OR (US); Turbo MAJUMDER, Portland, OR (US); Muhammad M. KHELLAH, Tigard, OR (US)

(21) Appl. No.: 16/795,516

(22) Filed: Feb. 19, 2020

(51) Int. Cl. G06F 16/2453; G06F 7/08; G06F 7/20; G11C 15/04

(52) U.S. Cl. CPC G06F 16/2453; G11C 15/04; G06F 7/20; G06F 7/08

(57) ABSTRACT

An apparatus is described. The apparatus includes a nearest neighbor search circuit to perform a search according to a first stage search and a second stage search. The nearest neighbor search circuit includes a first stage circuit and a second stage circuit. The first stage search circuit includes a hash logic circuit and a content addressable memory. The hash logic circuit is to generate a hash word from a input query vector. The hash word has B bands. The content addressable memory is to store hashes of a random access memory's data items. The hashes each have B bands. The content addressable memory is to compare the hashes against the hash word on a sequential band-by-band basis. The second stage circuit char the random access memory and a compare and sort circuit. The compare and sort circuit is to receive the input query vector. The random access memory has crosswise bit lines coupled to the compare and sort circuit. The compare and sort circuit is to identify k nearest ones of the data items whose hashes were selected by the content addressable memory.

### FIELD OF INVENTION

The field of invention pertains generally to the computing sciences, and, more specifically, to a nearest neighbor search logic circuit with reduced latency and power consumption.

### BACKGROUND

A number of applications depend on finding one or more specific items of data in a large database where the location of the items in the database is unknown. That is, the database needs to be searched in order to find the items of data. A class of searches, referred to as nearest neighbor searches (or “kNN” searches), return the k items of data in the database whose data content closest matches an input query item.

The challenge of performing kNN searches is exacerbated with the emergence of data-centric (e.g., cloud) computing, “big-data”, artificial intelligence, machine learning and other computationally intensive applications that execute from large databases, and, the general objective of keeping power consumption in check. Here, with database sizes becoming extremely large, the brute force method of comparing the input query item against every item of data in the database until the closest k matches are found is not feasible because too much time and energy are consumed per search query.

A better approach, depicted in FIG. 1, is to perform a two-stage search process in which a fast yet less accurate search is first performed 101 that can return the identity of a large (>>k) number of data items whose content is deemed similar to the searched for item. The large set of similar items is then searched with a second, more thorough and accurate search 102 to finally identify the k closest items. Here, the number of similar items identified from the first search, although potentially large when compared to k, is nevertheless small enough as compared to the size of the database such that they can each be searched through as thoroughly as needed to accurately identify the k closest items in a small amount of time and power consumption.

Nevertheless, implementing the overall search as a customized function within a semiconductor chip (e.g., as a kNN search accelerator) with minimal latency and power consumption offers challenges, particularly in the case of large databases that are to be searched.

### FIGURES

A better understanding of the present invention can be obtained from the following detailed description in conjunction with the following drawings, in which:

FIG. 1 shows a two-stage nearest neighbor search;

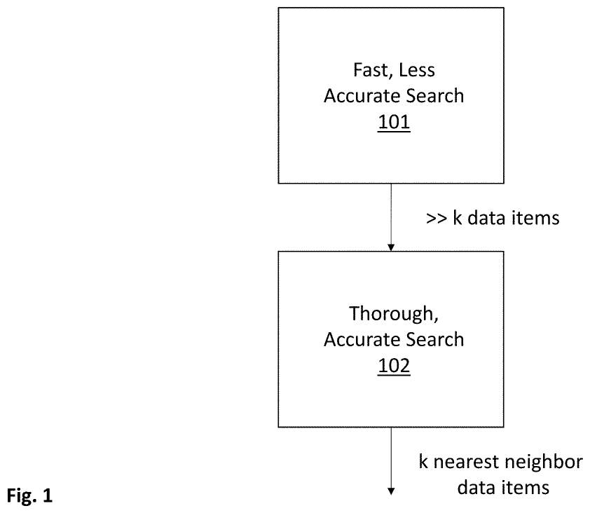

FIG. 2 shows a logic circuit for performing a nearest neighbor search;

FIG. 3 shows a method of performing a first stage search with a content addressable memory (CAM);

FIG. 4 shows a logic circuit for calculating a hash word;

FIG. 5 shows CAM circuit;

FIG. 6 shows a method for performing second stage search with a RAM;

FIG. 7 shows a logic circuit for performing a second state search;

FIG. 8 shows a RAM storage cell;

FIG. 9 shows a compare and sort circuit;

FIG. 10 shows a multi-core processor;

FIG. 11 shows a computing system.

### DETAILED DESCRIPTION

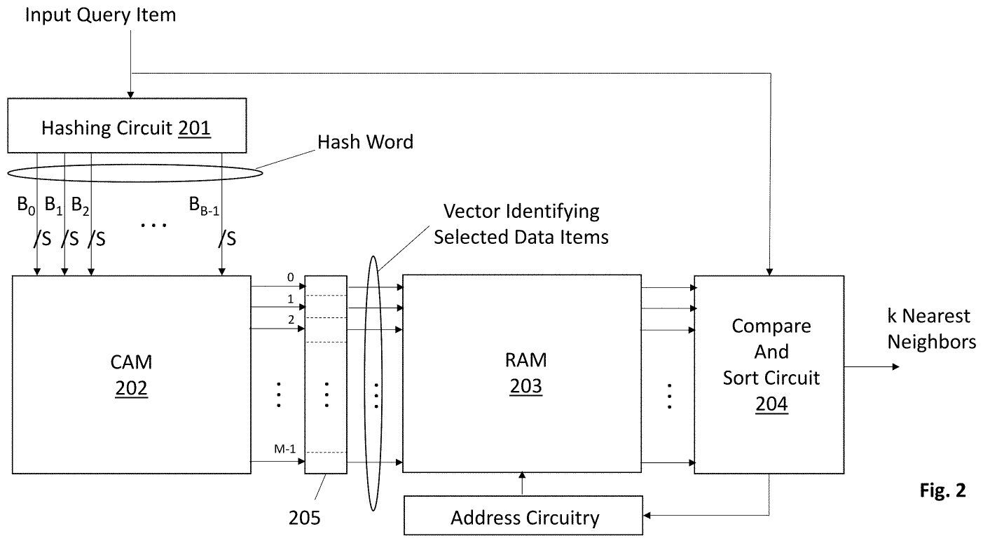

FIG. 2 shows a high-level view of a semiconductor chip circuit design that implements a two-stage kNN search process with a focus on reduced latency and power consumption. As observed in FIG. 2, the circuit includes a hashing logic circuit 201, a content addressable memory (CAM) 202, a random access memory (RAM) 203 and compare and sort logic circuitry 204. The RAM 203 corresponds to the database and contains the database's data items that are ultimately being searched over. As will be clear in the following discussion, the first search stage 101 is performed with the hashing logic circuit 201 and CAM 202, and, the second search stage 102 is performed with the RAM 203 and the compare and sort logic circuitry 204.

With respect to the first search stage 101, the hashing logic circuit 201 receives the input query term and generates an output “hash word” composed of B separate hash chunks or “bands” of S bits each. The CAM 202 contains entries that are the results of the same hashing algorithm used by the hashing logic circuitry 201 applied to each of the database's (RAM's) data items. That is, if the RAM 203 has M data items, the CAM 202 has M entries, where, each entry in the CAM 202 contains the hash word (composed of B bands of S bits) that results from application of the hashing algorithm to a different one of the RAM's data items.

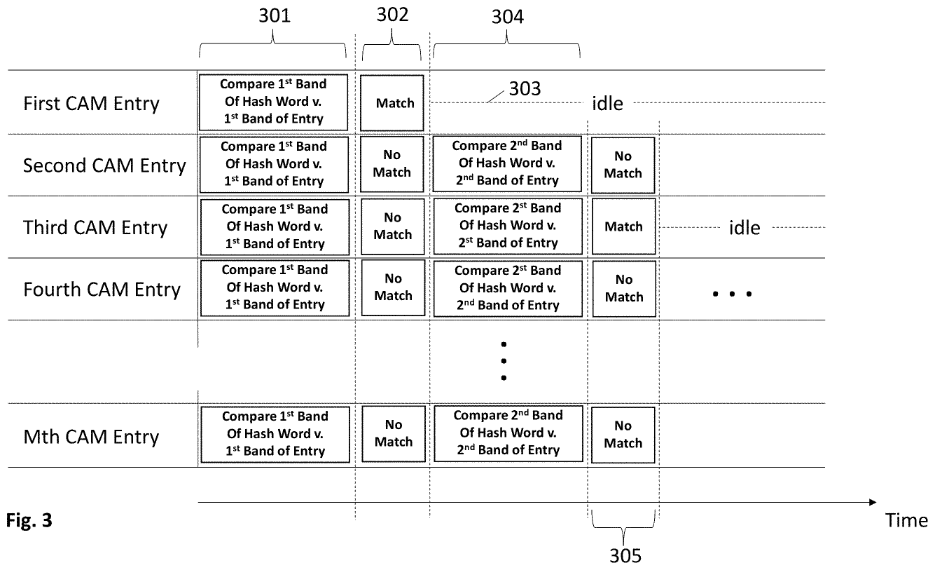

The CAM 202 receives the hash word from the hashing logic circuit 201 and compares the hash word against the CAM's entries. However, as will be described immediately below with respect to FIG. 3, the CAM 202 compares the hash word against the CAM entries on a successive, band by band, step-wise process.

That is, referring to FIG. 3, the CAM 202 first compares the first band of each CAM entry in parallel against the first band of the hash word 301. If there exists a bit for bit match between the first band of the hash word and the first band of any of the CAM entries, the entry is deemed to be sufficiently similar to the query input, and no more comparisons are carried out for that entry. Here, ceasing comparisons for entry after it demonstrates its first match to a band of the hash word, reduces the power consumed by the first stage search process.

In the particular example depicted in FIG. 3, there is a bit for bit match between the first band of the hash word and only the first band of the first CAM entry 302. As such, the CAM stops performing any further comparisons for the first CAM entry 303 but continues to perform comparisons for all other CAM entries 304.

In continuing comparisons for the CAM entries other than the first entry, the CAM compares the second band of each of these CAM entries in parallel against a corresponding second band of the hash word. Again, if the second band of any of these CAM entries exhibits a bit-for-bit match with the second band of the hash word, such entries are deemed to be sufficiently similar to the hash word for the first search stage, and no more comparisons are carried out for these entries going forward in order to save power. As observed in FIG. 3, only the third CAM entry exhibits a bit-for-bit match between its second band and the second band of the hash word 305. As such, the CAM stops performing any further comparisons for the first and third CAM entries going forward.

The process then continues in succession with each next comparison being performed on the next one of the bands of the hash word and the corresponding next one of the bands of the (remaining) entries in the CAM that have not been deemed sufficiently near the hash word. As matches are found over the succession of comparisons, commonly, the number of entries deemed sufficiently near the hash word grows and fewer CAM entries are subjected to comparisons resulting in increased power savings.

Eventually, the last one of the bands of the hash word is compared to the last one of the bands of the remaining CAM entries that have not been deemed sufficiently close to the hash word. If the last band of any of the remaining CAM entries exhibits a match to the last band of the hash word, such CAM entries are the last to be deemed sufficiently close to the hash word and the first stage of the search process is complete.

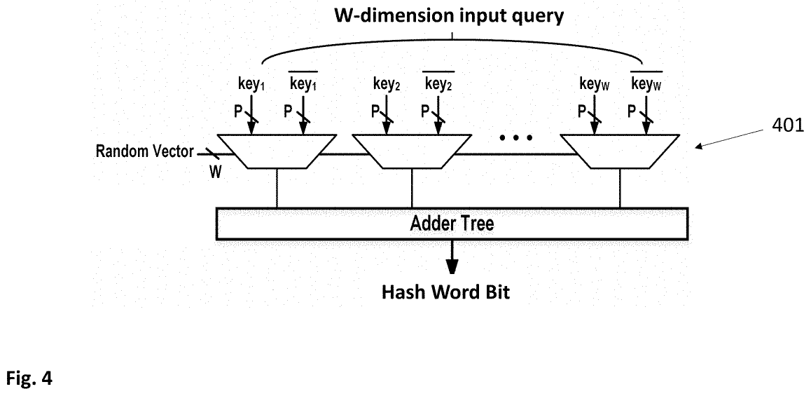

FIG. 4 shows an embodiment of a logic circuit design that could be used to implement the hashing logic circuit 201 of FIG. 2. For ease of drawing, FIG. 4 only shows the circuitry used to generate one bit of one band. That is, S instances of the circuit of FIG. 4 exist to generate a band of the hash word, and, B*S instances of the circuit of FIG. 4 exist to generate an entire hash word.

As observed in FIG. 4, the circuit includes W multiplexers 401. Each of the W multiplexers has a first input to receive P bits of the input query vector, referred to as a key. If the input query term is WP bits, there are W total keys in the input query term, then, each multiplexer receives a different one of these keys (key₁, key₂, etc.). Here, W such keys (=WP total bits=the full input query term) are used to generate a single bit of the hash word. Thus, in order to generate a hash word of length B*S, there are B*S different instances of the circuit of FIG. 4 (or the circuit of FIG. 4 is iterated through B*S times, or some combination of multiple circuit instances and iterations), where, each different instance/iteration selects a different group of P bits to define a set of W keys.

With respect to the operation of the circuit itself, each multiplexer receives a particular key and the logical inverse of that key. The channel select input of each multiplexer receives its own respective bit of a control vector, where, the control vector is essentially a random value (some bits are 1 s and the other bits are 0 s). Each multiplexer, therefore, presents at its output either its key or the logical inverse of its key depending on the bit of the control vector that is presented to its channel select input. The W outputs from the W multiplexers are then added. A particular bit of the summation result is chosen for the hash word bit. In an embodiment, the single generated bit corresponds to the most significant bit of the addition resultant determined by the adder tree.

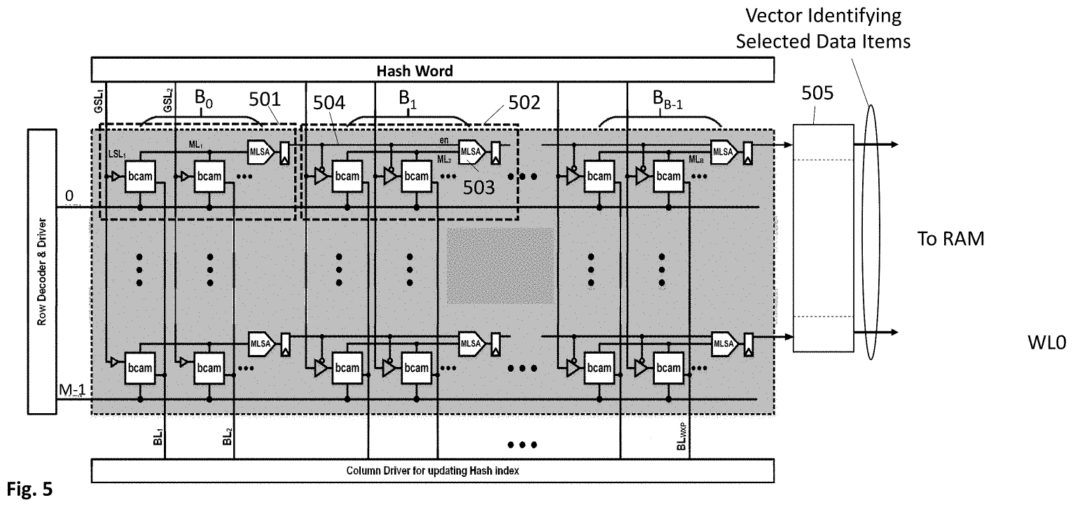

FIGS. 5 and show details of a design for the CAM circuit 202 of FIG. 2. For illustrative ease, FIG. 5 only labels pertinent features of neighboring comparison circuits 501, 502 that compare the respective bits of two neighboring bands of the hash word with the two corresponding bands of the hash value that resides in the first CAM entry. Here, each comparison circuit 501, 502 contains S comparison cells (“bcam”), where, each comparison cell stores one bit of the CAM entry's hash and compares it to a corresponding bit of the hash word.

Both comparison circuits 501, 502 use the bit line (“ML”) coupled to its respective comparison cells to perform a logical AND function across the collective output of its comparison cells. If all S comparisons performed by the S comparison cells indicate a match, the bit line will be pulled to a first logical value. By contrast, if one or more of these comparisons indicate a mismatch, the bit line will be pulled to a second logical value.

For example, in one embodiment, the bit line is passively pulled to a logic high (e.g., with a resistor), and, the comparison cells are designed to provide a high impedance output state in the case of a match. In the case where all comparison cells indicate a match, the comparison cells do not influence the bit line and the bit line manifests a logic high by the weak pull-up. By contrast, if one or more of the comparison cells indicate mis-match, the mis-matching cell(s) will actively drive the bit line low.

Comparison circuit 502 also includes an OR gate 503 that performs a logical OR on the aforementioned AND value from the match/mis-match bit line (ML₂) and the band match/mis-match result 504 generated from the immediately prior band. Here, from the discussion of FIG. 3, recall that comparisons are made on a band by basis in piece-wise succession. As such, while comparison circuit 502 is making its comparison, comparison circuit 501 will have already performed its comparison during the immediately prior cycle. Therefore the comparison result determined by circuit 501 for band 0 will be final and available while comparison circuit 502 is performing its comparison for band 1.

If OR gate 503 observes at logic high at either of its inputs (e.g., its local comparisons all match for band 1, and/or, the output of comparison circuit 501 indicates a match for band 0), the OR gate 503 will generate a logical high output. Essentially, a logical high at the output of the OR gate 503 means that comparison circuit 502 has observed a match on all of its S bits, and/or, the preceding comparison circuit 501 that performed a comparison on a preceding band of S bits observed a match on all of its S bits.

The output of OR gate 503 is tied to a respective enable input of each of the comparison cells of its immediately following comparison circuit so that, if the OR gate 503 provides a logically high output, the following comparison circuit does not perform any comparison as a power saving measure. The OR gate of the following comparison will also present a logic high in response to its prior OR gate 503 issuing a logic high. As such, once an comparison circuit issues an output indicating a match, the outputs of all subsequent comparison circuits will indicate a match which disables the comparison cells for the remainder of the CAM entry. The OR gate from the last comparison circuit for the last band (band B-1) enters a final match/mis-match decision bit for the first CAM entry into an element of a vector register 505 reserved for the first CAM entry. With each CAM entry operating concurrently with the first CAM entry according to the band-by-band comparison sequence, all CAM entries will, in parallel, register a match/mis-match final result into the vector register 505 after the last (B-1) band has been compared. The output of the vector register 505 presents the output of the first stage search.

Referring to FIG. 2, after the first stage nearest neighbor search performed by the hashing logic circuit 201 and CAM 202 circuits is complete and latched into the vector register 205, the second stage search is performed by comparing the full-width input query vector against selected ones of the full-width data items stored in random access memory (RAM) 203. In an embodiment, RAM 203 is a static random access memory (SRAM) but it is conceivable that other types of memory could be used (e.g., dynamic random access memory (DRAM), embedded on the same semiconductor chip as the hashing circuit and CAM, a three-dimensional non-volatile memory array that stacks resistive storage cells amongst the semiconductor chip's wiring layers, etc.).

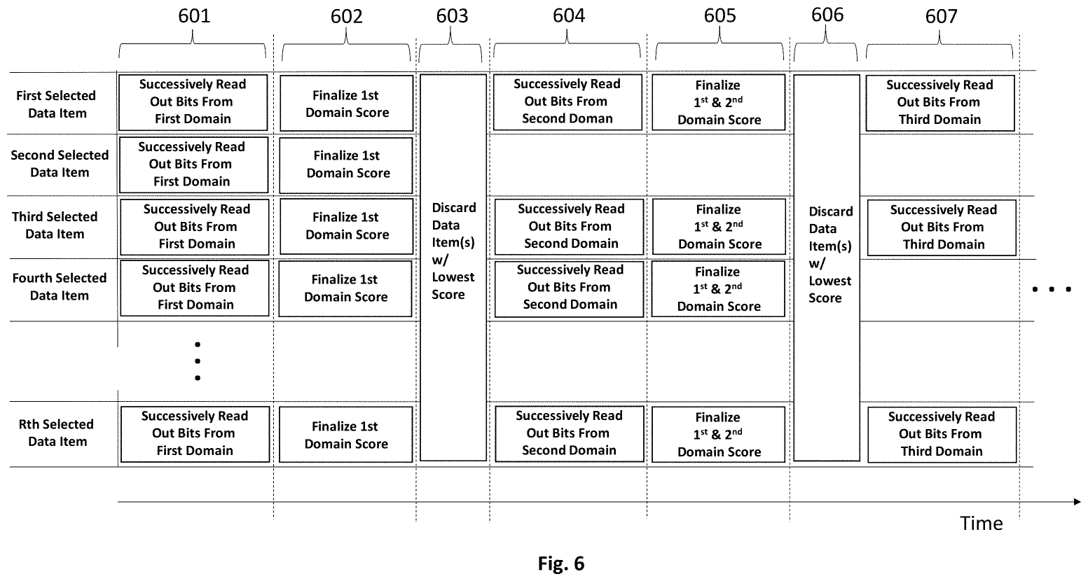

FIG. 6 demonstrates an embodiment of the second stage search as performed with the RAM 203 and compare and sort circuit 204. Here, the vector output of the first stage dictates which entries in the RAM are to be compared against the query vector and which entries in the RAM are to remain idle and not participate in the second stage search process. Specifically, comparisons are performed for those data items in the RAM that the output vector identifies as sufficiently close to the search query (“selected” data items) and comparisons are not performed for those data items that the output vector does not identify as sufficiently close to the search query. Here, not performing comparisons for data items that were not selected serves as a power-saving measure.

Similar to the approach of the hashing logic circuit 201 and CAM 202 of the first stage search process, in which comparisons are made in discrete bands of bits, the full query vector is viewed as being composed of discrete chunks of bits (referred to as “domains”) and comparisons of the full query vector against selected data items are made on a domain by domain basis. In an embodiment, there are T total domains and D bits per domain. As such, the size of the query vector and the data entries in the RAM is TD.

As observed in FIG. 6, during a first cycle 601 of the second stage search process, the bits from the first domain of every selected data item in the RAM are read out sequentially from the bits' corresponding storage cells along a common bit line.

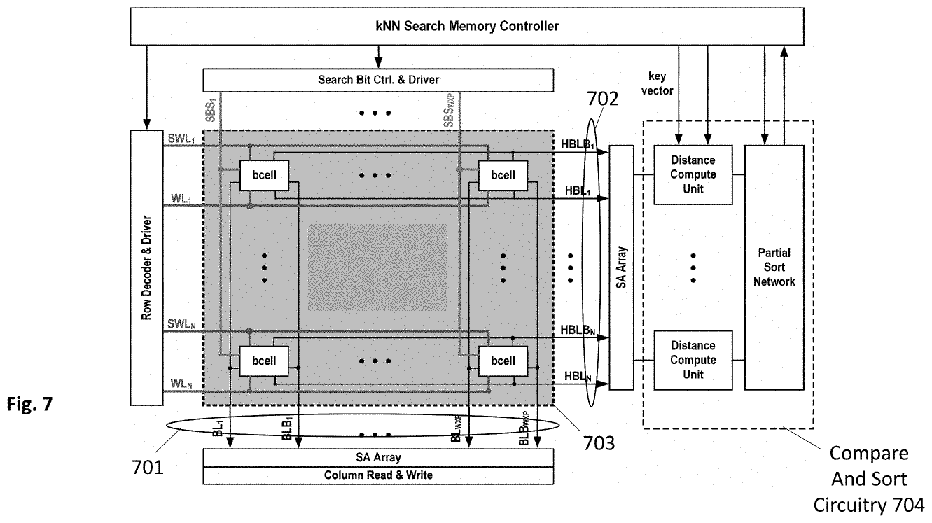

FIG. 7 shows an embodiment of the RAM design 703. As observed in Fig, 7, the RAM 703 includes standard bit lines 701 for nominal RAM read and write operations. The RAM 703 also includes crosswise bit lines 702, where, a crosswise bit line couples to each of the storage cells of the same data item in the RAM 703. By coupling a crosswise bit line to each of the storage cells of a data item, the bits of a data item in RAM can be read out sequentially on the crosswise bit line.

Thus, in order to read the bits of each selected data item's first domain along the data item's crosswise bit line, according to a first phase, a first control signal that is coupled to the highest ordered bit in the first domain (SBS₁) of each data item is activated. The storage cells of only those data items that were selected by the first search phase respond to the control signal. The highest ordered bit in the first domain of each selected data item is then presented on the data item's crosswise bit line for sampling by the compare and sort circuitry 704. As depicted in FIG. 7, the crosswise bit lines are implemented differentially so that there are two crosswise bit lines per data entry in the RAM and a read out signal in the crosswise direction is differential.

Then, according to a second phase, a second control signal that is coupled to the second-highest ordered bit in the first domain (SBS₂—not shown in FIG. 7) of each data item is activated. Again, only the selected data items respond to the control signal. The second highest ordered bit in the first domain of each selected data item is then presented on the data item's crosswise bit lines for sampling by the compare and sort circuitry 704. The process then continues until the D^{th} bit in the first domain (which is the last bit in the first domain) of each selected data item is read out.

Again, the phases are performed in parallel across all selected data items, thus, the crosswise bit lines of the selected data items will present a succession of bits in parallel across the D phases of the readout process. As observed in FIG. 7, the crosswise bit line 702 for each data item is coupled to the compare and sort circuit 704, which processes, in parallel, each of the bits sequences from each of the selected data items as they are received from their respective crosswise bit lines.

In particular, for each selected data item, the compare and sort circuit 704 first compares the sequence of D bits for the first domain that is received from the data item's crosswise bit line against the corresponding D bits for the first domain in the search vector. In an embodiment, the comparison is mathematically performed as an inner product. Here, the inner product yields a scalar value that can be deemed a “score” whose value increases with increasing higher ordered bits that match and decreases with increasing higher ordered bits that do not match.

Notably, the inner product performed by the compare and sort circuit 704, can be pipelined with the readout process of the selected data entries. That is, for instance, while a next bit is being read out from the appropriate storage cell of each of the selected data entries, the prior bit is being compared or otherwise used in a calculation to determine whether the prior bit matches its counterpart in the search vector.

At the conclusion of the comparison of the D bits of the first domain, referring to FIG. 6, a comparison score will have been determined for all selected entries 602. Here, as discussed above, the overall search is to return an output that identifies the k closest neighbors to the search term. The comparison and sort circuit 704 then identifies the one or more data items having the lowest score and removes them from further consideration as the nearest neighbor (their status changes from selected to unselected) if the number of surviving selected entries remains greater than k 603. As observed in FIG. 6, at least the second selected data item achieved the lowest score and is eliminated from further consideration. The elimination of the second selected data item corresponds to a power-saving feature.

The process then repeats 604, 605, 606 with the remaining selected data entries for a next, lesser order domain of D bits. For each remaining selected entry, the entry's earlier score is accumulated with its newly determined score. However, as the process flows in the direction from the most significant bit to the least significant bit, later scores have less weight in the total score for the data entries than earlier scores. Again, the next one or more data entries having the lowest total score are eliminated from consideration (their status changes from selected to non-selected) 606. As observed in FIG. 6, at the conclusion of the processing of the second domain, at least the fourth selected data is removed from further consideration.

The iterations then continue until the number of remaining data entries reaches k, or, the last domain of D bits is processed. In the case of the former, the k remaining data entries are returned as the result of the search. In the case of the later, the sorting circuit chooses the set of k entries having the highest total score.

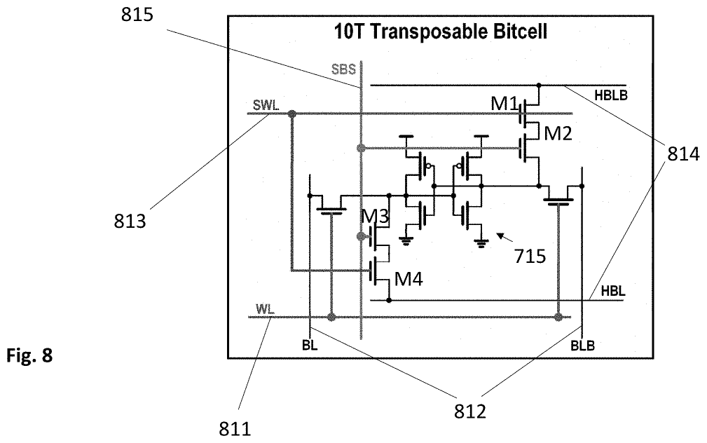

FIG. 8 shows an embodiment of a storage cell for the RAM 703 of FIG. 7. As observed in FIG. 8, the cell includes a nominal word line 811 and nominal differential bit lines 812 for nominal reads/writes from/to the cell. That is, the case of a nominal read from the cell, nominal word line 811 is activated and the read data appears on nominal bit lines 812. Likewise, in the case of a write, nominal word line 811 is activated and the write data is presented on nominal bit lines 812.

By contrast, when the cell is to be read for purposes of performing the second stage of a search process as described at length above, the search word line 813 is activated. Here, search word line 813 is activated when the data entry that the storage cell belongs to is selected by the vector output of the first search stage process. The search word line 813 remains active unless and until data entry is discarded from consideration as the nearest neighbor. When the domain the cell belongs to is being read and its the cells turn/phase to provide its data on the differential crosswise bit lines 814, the search strobe line 815 is activated. With both the search word and search strobe lines 813, 815 being active, transistors M1, M2, M3 and M4 are all ON which causes the data stored by latch 816 to be presented on the crosswise bit lines 814.

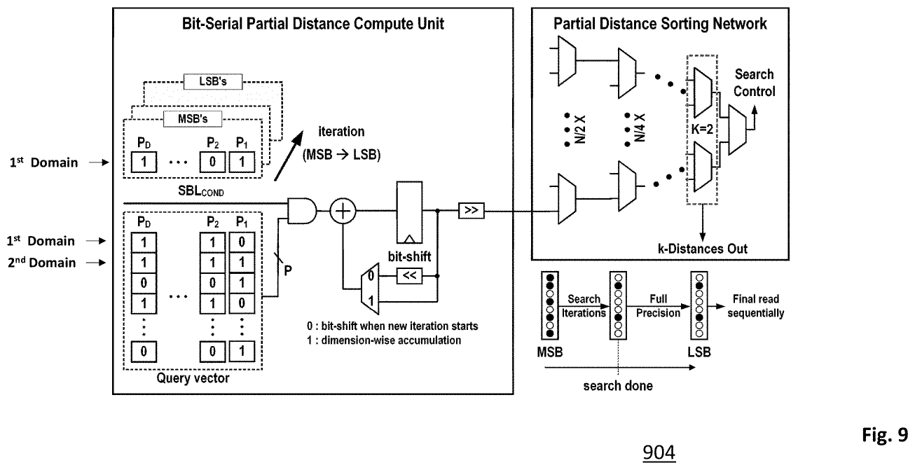

FIG. 9 shows an embodiment 904 of circuitry within the compare and sort circuit 704 of FIG. 7. As observed in FIG. 7, the compare and sort circuit 704 includes a plurality of distance compute circuits to perform the comparisons of the domain bitstreams from the different data entries against their corresponding search query domain term. For illustrative ease FIG. 9 only shows one instance of a distance compute circuit.

As observed in FIG. 9, the distance compute circuit includes an AND gate to compare each bit of data entry's domain bitstream against its corresponding bit in the corresponding domain of the search query. Each match causes a count or score value held in a register to increment. As comparisons are made in the most significant to the least significant direction across domains and within domains, a shift register is used to ensure that matches on more significant bits result in increments of higher ordered bits of the score value.

A distance sorting network ripples higher score values from the distance compute circuits closer to the end of the network. Thus, score values that ripple forward the least are candidates for elimination from consideration as the nearest neighbor.

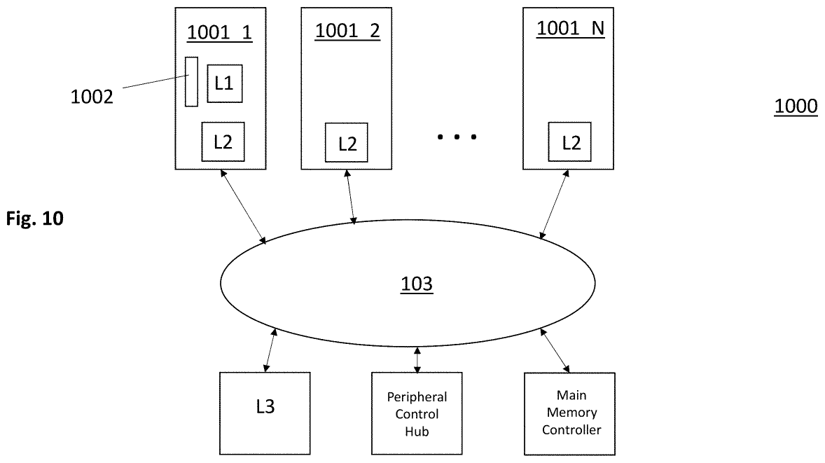

FIG. 10 shows an embodiment of a multi-core processor 1000. As observed in FIG. 10, the multicore processor 1000 includes multiple (e.g., general-purpose) processing cores 1001. Each processing core includes multiple instruction execution pipelines (only one instruction execution pipeline 1002 is shown in FIG. 10 for illustrative ease). Here, each instruction execution pipeline has its own L1 cache (only one L1 cache is shown in FIG. 10 for illustrative ease). Each processing core also includes an L2 cache that services its pipelines as their next lower cache from their respective L1 caches. The processing cores 1001 are coupled to one another and an L3 cache by way of an internal network 1003.

Here, as observed in FIG. 10, an instance of the search circuit of FIG. 2 can be disposed at any/all of the L1, L2 and L3 caches of the processor. As such, any/all of the L1, L2 and L3 caches can perform a nearest neighbor search as described at length above. Thus, the nearest neighbor search can be applied, e.g., to any field that desires fast and energy-efficient content-based searching on a large scale database. A possible application is a cloud-scale storage solution for efficient high dimensional data access by searching for similar data.

The instruction set architecture (ISA) of the processing cores could include a special instruction to execute the nearest neighbor search in any/all of the processor's caches. Such instruction could specify a nearest neighbor search opcode and a search query vector and target cache (e.g., L1 cache, L2 cache, L3 caches, all caches, etc.) as input operands.

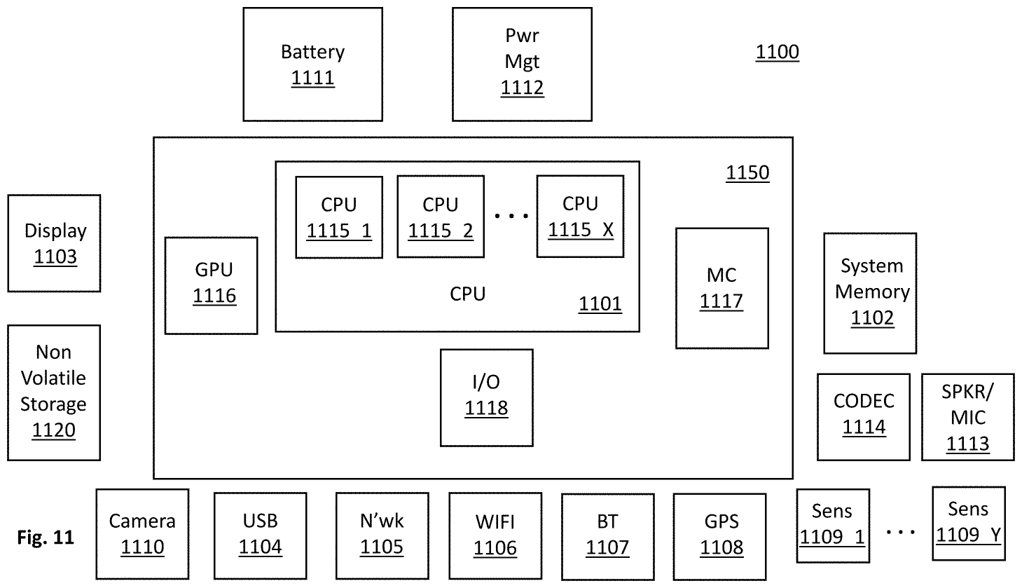

FIG. 11 provides an exemplary depiction of a computing system 1100 (e.g., a smartphone, a tablet computer, a laptop computer, a desktop computer, a server computer, etc.). As observed in FIG. 11, the basic computing system 1100 may include a central processing unit (CPU) 1101 (which may include, e.g., a plurality of general-purpose processing cores 1115_1 through 1115_X) and the main memory controller 1117 disposed on a multi-core processor or applications processor, system memory 1102, a display 1103 (e.g., touchscreen, flat-panel), a local wired point-to-point link (e.g., USB) interface 1104, various network I/O functions 1105 (such as an Ethernet interface and/or cellular modem subsystem), a wireless local area network (e.g., WiFi) interface 1106, a wireless point-to-point link (e.g., Bluetooth) interface 1107 and a Global Positioning System interface 1108, various sensors 1109_1 through 1109_Y, one or more cameras 1110, a battery 1111, a power management control unit 1112, a speaker and microphone 1113 and an audio coder/decoder 1114.

An application processor or multi-core processor 1150 may include one or more general-purpose processing cores 1115 within its CPU 1101, one or more graphical processing units 1116, a memory management function 1117 (e.g., a memory controller) and an I/O control function 1118. The general-purpose processing cores 1115 typically execute the system and application software of the computing system. The graphics processing unit 1116 typically executes graphics intensive functions to, e.g., generate graphics information that is presented on the display 1103. The memory control function 1117 interfaces with the system memory 1102 to write/read data to/from system memory 1102.

Any of the system memory 1102 and/or non volatile mass storage 1120 can be composed with a three dimensional non volatile random access memory composed, e.g., of an emerging non volatile storage cell technology. Examples include Optane™ memory from Intel Corporation, QuantX™ from Micron Corporation, and/or other types of resistive non-volatile memory cells integrated amongst the interconnect wiring of a semiconductor chip (e.g., resistive random access memory (ReRAM), ferroelectric random access memory (FeRAM), spin transfer torque random access memory (STT-RAM), etc.). Mass storage 1120 at least can also be composed of flash memory (e.g., NAND flash).

The computing system can further include L1, L2, L3 or even deeper CPU level caches that have associated nearest neighbor search logic circuitry as described at length above. Conceivably system memory could also perform nearest neighbor searching with similar circuitry (e.g., with a DRAM RAM having crosswise bit lines as described at length above).

Each of the touchscreen display 1103, the communication interfaces 1104-1107, the GPS interface 1108, the sensors 1109, the camera(s) 1110, and the speaker/microphone codec 1113, 1114 all can be viewed as various forms of I/O (input and/or output) relative to the overall computing system including, where appropriate, an integrated peripheral device as well (e.g., the one or more cameras 1110). Depending on implementation, various ones of these I/O components may be integrated on the applications processor/multi-core processor 1150 or may be located off the die or outside the package of the applications processor/multi-core processor 1150. The power management control unit 1112 generally controls the power consumption of the system 1100.

Embodiments of the invention may include various processes as set forth above. The processes may be embodied in machine-executable instructions. The instructions can be used to cause a general-purpose or special-purpose processor to perform certain processes. Alternatively, these processes may be performed by specific/custom hardware components that contain hardwired logic circuitry or programmable logic circuitry (e.g., FPGA, PLD) for performing the processes, or by any combination of programmed computer components and custom hardware components.

Elements of the present invention may also be provided as a machine-readable medium for storing the machine-executable instructions. The machine-readable medium may include, but is not limited to, floppy diskettes, optical disks, CD-ROMs, and magneto-optical disks, FLASH memory, ROMs, RAMs, EPROMs, EEPROMs, magnetic or optical cards, propagation media or other type of media/machine-readable medium suitable for storing electronic instructions. For example, the present invention may be downloaded as a computer program which may be transferred from a remote computer (e.g., a server) to a requesting computer (e.g., a client) by way of data signals embodied in a carrier wave or other propagation medium via a communication link (e.g., a modem or network connection).

In the foregoing specification, the invention has been described with reference to specific exemplary embodiments thereof. It will, however, be evident that various modifications and changes may be made thereto without departing from the broader spirit and scope of the invention as set forth in the appended claims. The specification and drawings are, accordingly, to be regarded in an illustrative rather than a restrictive sense.

1. An apparatus, comprising:
a nearest neighbor search circuit to perform a search according to a first stage search and a second stage search, the nearest neighbor search circuit comprising:
a first stage search circuit comprising a hash logic circuit and a content addressable memory, the hash logic circuit to generate a hash word from an input query vector, the hash word comprising B bands, the content addressable memory to store hashes of a random access memory's data items, the hashes each comprising B bands, the content addressable memory to compare the hashes against the hash word on a sequential band-by-band basis; and,
a second stage circuit comprising the random access memory and a compare and sort circuit, the compare and sort circuit to receive the input query vector, the random access memory comprising crosswise bit lines coupled to the compare and sort circuit, the compare and sort circuit to identify k nearest ones of the data items whose hashes were selected by the content addressable memory.

2. The apparatus of claim 1 wherein the content addressable memory is to stop performing comparisons on selected ones of the hashes once they are found to include a band that matches a corresponding band of the hash word.

3. The apparatus of claim 2 wherein the crosswise bit lines are to sequentially transport bits of the data items whose hashes were selected by the content addressable memory to the compare and sort circuit.

4. The apparatus of claim 2 wherein the random access memory is to stop sending bits of data items to the compare and sort circuit that have been identified by the compare and sort circuit as not being members of the k nearest ones of the data items.

5. The apparatus of claim 1 wherein the crosswise bit lines are to sequentially transport bits of the data items whose hashes were selected by the content addressable memory to the compare and sort circuit.

6. The apparatus of claim 1 wherein the random access memory is to stop sending bits of data items to the compare and sort circuit that have been identified by the compare and sort circuit as not being members of the k nearest ones of the data items.

7. The apparatus of claim 1 wherein the nearest neighbor search circuit is instantiated with a cache to perform a nearest k neighbor search within the cache.

8. The apparatus of claim 7 wherein the cache is an L1 cache.

9. The apparatus of claim 7 wherein the cache is an L2 cache.

10. The apparatus of claim 7 wherein the cache is an L3 cache.

11. A computing system, comprising:
a plurality of processing cores;
a system memory;
a system memory controller between the system memory and the plurality of processing cores;
a cache, the cache having a nearest neighbor search circuit to perform a nearest neighbor search in the cache, the nearest neighbor search circuit comprising:
a first stage search circuit comprising a hash logic circuit and a content addressable memory, the hash logic circuit to generate a hash word from a input query vector, the hash word comprising B bands, the content addressable memory to store hashes of a random access memory's data items, the hashes each comprising B bands, the content addressable memory to compare the hashes against the hash word on a sequential band-by-band basis; and,
a second stage circuit comprising the random access memory and a compare and sort circuit, the compare and sort circuit to receive the input query vector, the random access memory comprising crosswise bit lines coupled to the compare and sort circuit, the compare and sort circuit to identify k nearest ones of the data items whose hashes were selected by the content addressable memory.

12. The computing system of claim 11 wherein the content addressable memory is to stop performing comparisons on selected ones of the hashes once they are found to include a band that matches a corresponding band of the hash word.

13. The computing system of claim 12 wherein the crosswise bit lines are to sequentially transport bits of the data items whose hashes were selected by the content addressable memory to the compare and sort circuit.

14. The computing system of claim 12 wherein the random access memory is to stop sending bits of data items to the compare and sort circuit that have been identified by the compare and sort circuit as not being members of the k nearest ones of the data items.

15. The computing system of claim 11 wherein the crosswise bit lines are to sequentially transport bits of the data items whose hashes were selected by the content addressable memory to the compare and sort circuit.

16. The computing system of claim 11 wherein the random access memory is to stop sending bits of data items to the compare and sort circuit that have been identified by the compare and sort circuit as not being members of the k nearest ones of the data items.

17. A method, comprising:
generating a hash word from a search query vector, the hash word comprising B bands;
comparing the hash word on a band by band basis against hashes of data entries, each of the hashes comprising B bands, the comparing including stopping any further comparing on any of the data entries once they have been found to have a band that matches its corresponding band in the hash word; and,
comparing against the search query vector, on a domain by domain basis, those of the data entries that were found to have a band that matches its corresponding band in the hash word, and, eliminating farther ones of the data entries that were found to have a band that matches its corresponding band in the hash word from further comparisons against the search query until a set of nearest k neighbors is reached.

18. The method of claim 17 wherein the comparing of the hash word is performed by a CAM.

19. The method of claim 17 wherein the comparing against the search query is performed by a comparison circuit coupled to a random access memory in which the data entries are stored.

20. The method of claim 17 wherein the data entries are stored in a cache.
